(19) United States
(12) Patent Application Publication
(10) Pub. No.: US 2016/0005459 A1
(43) Pub. Date: Jan. 7, 2016

(54) NONVOLATILE SEMICONDUCTOR MEMORY DEVICE

(71) Applicant: Kabushiki Kaisha Toshiba, Minato-ku (JP)

(72) Inventors: Rieko FUNATSUKI, Kamakura-shi (JP); Koichi FUKUDA, Yokohama-shi (JP)

(73) Assignee: Kabushiki Kaisha Toshiba, Minato-ku (JP)

(21) Appl. No.: 14/852,972

(22) Filed: Sep. 14, 2015

Related U.S. Application Data
(62) Division of application No. 13/966,421, filed on Aug. 14, 2013.
(60) Provisional application No. 61/770,711, filed on Feb. 28, 2013.

(51) Int. Cl. G11C 11/56; G11C 16/26

(52) U.S. Cl. CPC G11C 11/5642; G11C 16/26

(57) ABSTRACT

A nonvolatile semiconductor memory device according to an embodiment includes a memory cell array having a plurality of memory cell transistors connected in series therein; a plurality of bit lines; and a control circuit for executing a read operation. The control circuit is configured capable of executing the read operation, the read operation charging the bit line and applying a read voltage to the control gate electrode of the memory cell transistor to determine whether the memory cell transistor is conductive and the bit line discharges or not. The control circuit is configured to, in the read operation, be capable of executing the read operation targeting the memory cell transistors connected to a portion of the plurality of bit lines, and not execute a charging operation in those other of the bit lines where the connected memory cell transistors are not targeted by the read operation.

### CROSS REFERENCE TO RELATED APPLICATION

This application is a divisional of U.S. patent application Ser. No. 13/966,421 filed Aug. 14, 2013, which is based upon and claims the benefit of priority from Provisional Application No. 61/770,711, filed on Feb. 28, 2013, the entire contents of both of which are incorporated herein by reference.

### BACKGROUND

1. Field

The present invention relates to a nonvolatile semiconductor memory device, in particular to a nonvolatile semiconductor memory device configured to employ an electrically rewritable nonvolatile memory cell.

2. Description of the Related Art

A NAND type flash memory is a known example of a nonvolatile semiconductor memory device that is electrically rewritable and capable of being highly integrated. In the NAND type flash memory, a plurality of memory cells are series connected in a form where a source/drain diffusion layer is shared by fellow adjacent memory cells, the plurality of memory cells thereby configuring a NAND cell unit. The two ends of the NAND cell unit are connected, via select gate transistors, to a bit line and a source line, respectively. Such a NAND cell unit configuration enables small unit cell area and large capacity storage compared to a NOR type flash memory.

A sense amplifier in a semiconductor memory device such as the NAND type flash memory determines data basically by detecting presence/absence or magnitude of a cell current flowing according to data of the memory cell. The sense amplifier is connected to a data line (bit line) to which, usually, numerous memory cells are connected. Types of sensing systems in the sense amplifier may be broadly divided into a voltage detecting type and a current detecting type.

A current detecting type sense amplifier performs data sensing by passing a read current through the memory cell via the bit line. Ultimately, data determination at a sense node linked to the bit line amounts to detecting a difference in voltage of the sense node based on a difference in cell current. It is required that a read operation employing this current detecting type sense amplifier be executed at high speed.

### BRIEF DESCRIPTION OF THE DRAWINGS

FIG. 1 is a view showing a memory cell array and peripheral circuits in a nonvolatile semiconductor memory device according to a first embodiment.

FIG. 2 is a circuit diagram of the memory cell array in the nonvolatile semiconductor memory device according to the first embodiment.

FIG. 3 is a circuit diagram of a sense amplifier in the nonvolatile semiconductor memory device according to the first embodiment.

FIG. 4 is a view showing peripheral circuits in the nonvolatile semiconductor memory device according to the first embodiment.

FIG. 5 is a view explaining a data storage state in the nonvolatile semiconductor memory device according to the first embodiment.

FIG. 6 is a waveform chart for explaining a read operation in the nonvolatile semiconductor memory device according to the first embodiment.

FIG. 7 is a view showing the memory cell array and peripheral circuits in the nonvolatile semiconductor memory device according to the first embodiment.

FIG. 8 is a view explaining a data storage state in a nonvolatile semiconductor memory device according to a second embodiment.

FIG. 9 is a waveform chart for explaining a read operation in the nonvolatile semiconductor memory device according to the second embodiment.

FIG. 10 is a view explaining a data storage state in a nonvolatile semiconductor memory device according to a third embodiment.

FIG. 11 is a waveform chart for explaining a verify operation in the nonvolatile semiconductor memory device according to the third embodiment.

FIG. 12 is a view explaining a data storage state in a nonvolatile semiconductor memory device according to another example of the third embodiment.

FIG. 13 is a view showing a memory cell array and peripheral circuits in a nonvolatile semiconductor memory device according to a fourth embodiment.

FIG. 14 is a view showing the memory cell array and peripheral circuits in the nonvolatile semiconductor memory device according to the fourth embodiment.

FIG. 15 is a view showing the memory cell array and peripheral circuits in the nonvolatile semiconductor memory device according to another example of the fourth embodiment.

### DETAILED DESCRIPTION

A nonvolatile semiconductor memory device according to an embodiment comprises: a memory cell array configured as an arrangement of NAND cell units, each of the NAND cell units including a memory string and select transistors, the memory string being configured having a plurality of memory cell transistors connected in series therein, and the select transistors being respectively connected to both ends of the memory string; a plurality of word lines respectively connected to control gate electrodes of the plurality of memory cell transistors; a plurality of bit lines respectively connected to first ends of the NAND cell units; a source line connected to second ends of the NAND cell units; and a control circuit for executing a read operation for data read, the read operation determining whether a threshold voltage of the memory cell transistor is a certain value or not. The control circuit has a plurality of sense amplifiers configured to execute the read operation to the memory cell transistor, each of the sense amplifiers being connected to a corresponding one of the plurality of bit lines. The control circuit is configured capable of executing the read operation, the read operation charging the bit line and applying a read voltage to the control gate electrode of the memory cell transistor to determine whether the memory cell transistor is conductive and the bit line discharges or not. The control circuit is configured to, in the read operation, be capable of executing the read operation targeting the memory cell transistors connected to a portion of the plurality of bit lines, and not execute a charging operation in those other of the bit lines where the connected memory cell transistors are not targeted by the read operation.

Next, embodiments of the present invention are described in detail with reference to the drawings. Note that in notation of the drawings in the embodiments below, places having identical configurations are assigned with identical symbols, and duplicated descriptions of such places are omitted. Moreover, the embodiments below are described assuming the nonvolatile semiconductor memory device to be a NAND type flash memory employing a memory cell (memory cell transistor) having a stacked gate structure. However, this configuration is merely one example, and the present invention is of course not limited to such a configuration.

### First Embodiment

### Configuration of Nonvolatile Semiconductor Memory Device according to First Embodiment

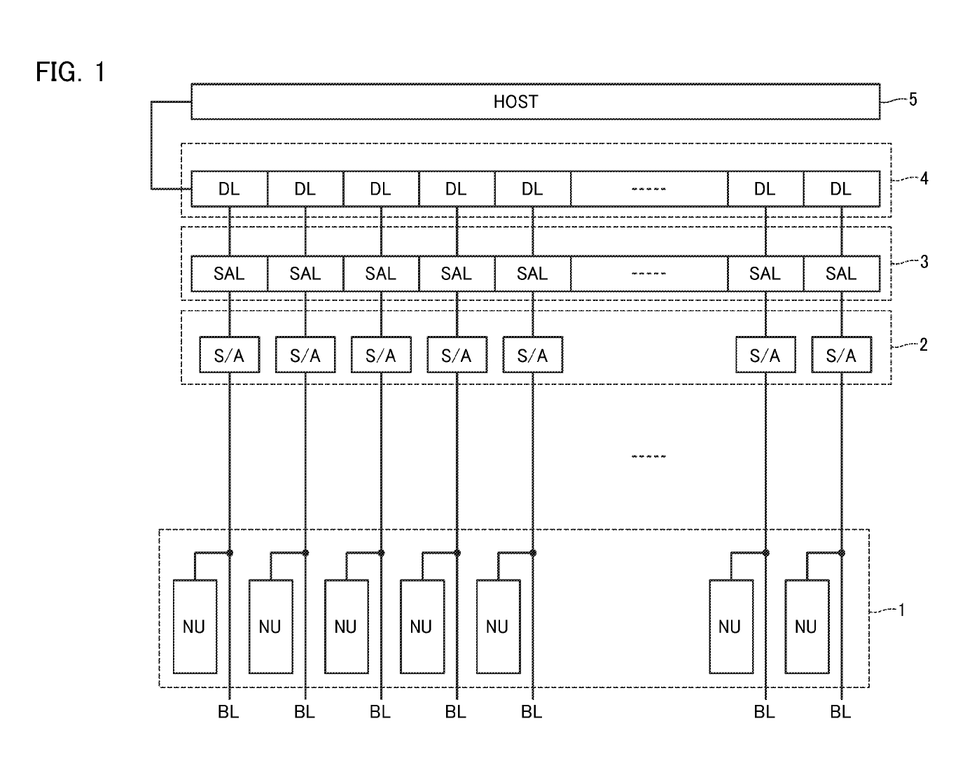

A configuration of a nonvolatile semiconductor memory device according to a first embodiment of the present invention is described below with reference to FIGS. 1 through 4.

FIG. 1 is a block diagram showing a memory cell array and peripheral circuits of a NAND type flash memory in the present embodiment. This nonvolatile memory comprises a memory cell array 1 having NAND strings NU disposed therein, each of the NAND strings NU having nonvolatile memory cells connected in series therein. Provided at positions adjacent in a bit line BL direction of the memory cell array 1 are a sense amplifier circuit 2, a sense amplifier latch circuit 3 and data latch circuit 4, and a host device 5. The sense amplifier circuit 2 controls a bit line BL in the memory cell array 1 to perform data read from the memory cell. The sense amplifier latch circuit 3 and data latch circuit 4 are for holding data required in the likes of read/write from/to the memory cell array 1. The host device 5 is for performing operation control of the semiconductor memory device overall. The host device 5 performs data transfer control or operation control, and so on, based on a state of the memory cell array 1.

[Memory Cell Array and Peripheral Circuits]

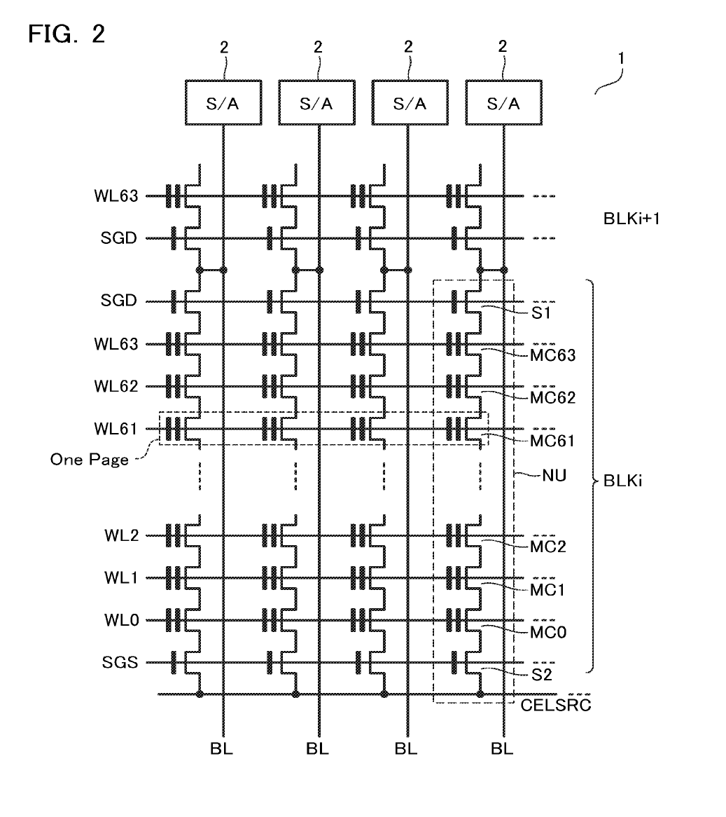

FIG. 2 is a view showing the memory cell array 1 and the sense amplifier circuit 2 in the NAND type flash memory according to the present embodiment.

As shown in FIG. 2, the memory cell array 1 is configured as an arrangement of NAND cell units (NAND strings) NU, each of the NAND cell units NU having a plurality of electrically rewritable nonvolatile memory cells (in the example of FIG. 2, 64 memory cells) MC0˜MC63 connected in series therein. A plurality of the NAND strings NU share word lines WL to form one block BLK.

One block BLK forms a single unit with respect to a data erase operation. In addition, the memory cell MC is assumed to include an N type source/drain region formed in a P type well of a silicon substrate and to have a stacked gate structure including a control gate and a floating gate, the floating gate acting as a charge storage layer. In the NAND type flash memory, an amount of charge held in this floating gate is changed by a write operation and an erase operation. This causes a threshold voltage of the memory cell MC to be changed, whereby one bit or multiple bits of data are stored in one memory cell MC. As shown in FIG. 2, when one bit of data is stored in one memory cell MC, the memory cells MC formed along one of the word lines WL intersecting the NAND cell units NU store one page of data. When, for example, 16 KB of data are stored in each page in the memory cell array 1, this leads to 16 KB of NAND cell units NU being included in one block BLK.

As shown in FIG. 2, the NAND string NU has its one end connected to the bit line BL, via a select gate transistor S1, and has its other end connected to a common source line CELSRC via a select gate transistor S2. The select gate transistors S1 and S2 have their gates connected to select gate lines SGD and SGS, respectively. Moreover, the memory cells MC0˜MC63 have their control gates connected to word lines WL0˜WL63, respectively.

The sense amplifier circuit 2 provided for read of cell data is disposed on a side of one end of the bit line BL. Moreover, although omitted from the drawing in FIG. 2, a row decoder for performing selective drive of the word lines and select gate lines is disposed on a side of one end of the word line WL.

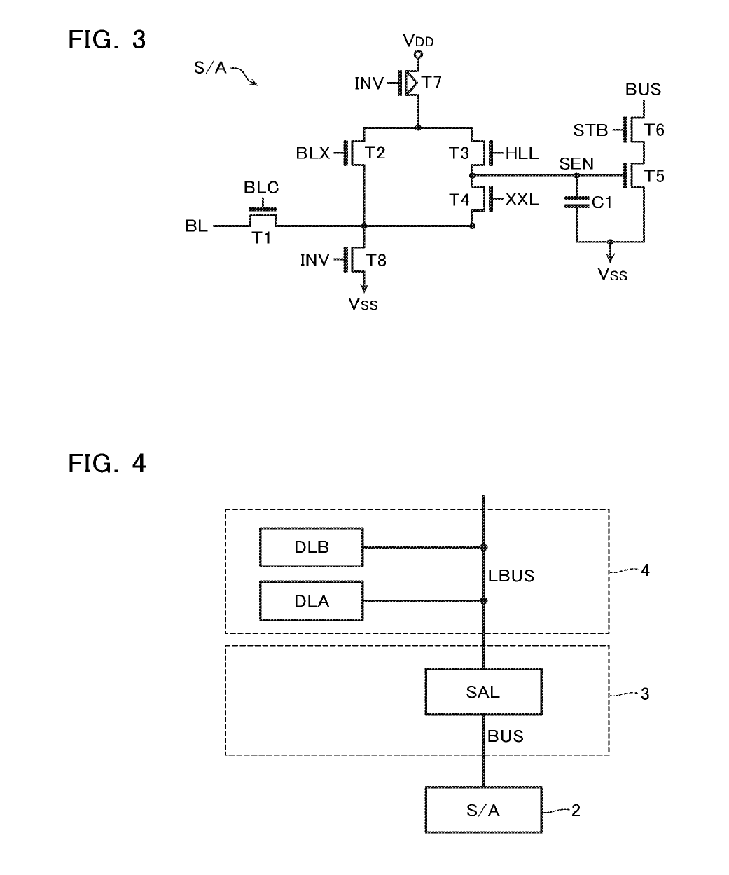

FIG. 3 is a view showing an example of a circuit configuration of the sense amplifier circuit 2 being part of a read circuit. The sense amplifier circuit 2 is provided between the bit line BL and the sense amplifier latch circuit 3 that holds a sensing result of the sense amplifier circuit 2. In the sense amplifier circuit 2, a sense amplifier S/A employed in the read operation is provided to each of the bit lines BL.

The sense amplifier S/A includes: a clamp-dedicated NMOS transistor T1 having its gate supplied with a control voltage (control signal) BLC; a current continuation supply-dedicated NMOS transistor T2 connected to a power supply terminal VDD and having its gate supplied with a control voltage BLX; a pre-charge-dedicated NMOS transistor T3 connected between the power supply terminal VDD and a detection node SEN and having its gate supplied with a control voltage HLL; a charge transfer-dedicated NMOS transistor T4 connected to the detection node SEN and having its gate supplied with a control voltage XXL; a capacitor C1 connected between the detection node SEN and a ground terminal VSS; an NMOS transistor T5 having the detection node SEN connected to its gate; an NMOS transistor T6 connected between a transfer bus BUS linking to the data latch circuit 4 and the transistor T5 and having its gate supplied with a control voltage STB; a PMOS transistor T7 connected to the power supply terminal VDD and having its gate supplied with a control signal INV; and an NMOS transistor T8 connected to the ground terminal VSS and having its gate supplied with the control signal INV.

The control voltages (control signals) BLC, BLX, HLL, and XXL shown in FIG. 3 are voltages (signals) shared by a plurality of the sense amplifiers S/A. Moreover, the transfer bus BUS and the signal INV are connected to a sense amplifier latch SAL mentioned later, the signal INV becomes inverted data of the sense amplifier latch SAL, and a value of the transfer bus BUS is controlled in conjunction with data of the sense amplifier latch SAL according to an operation. In other words, a state of the transfer bus BUS or the signal INV can be controlled on an individual sense amplifier S/A basis, that is, on a bit line BL basis.

FIG. 4 shows a configuration of the sense amplifier latch circuit 3 and the data latch circuit 4 connected to the sense amplifier circuit 2. The sense amplifier latch circuit 3 and the data latch circuit 4 are provided connected to the sense amplifier circuit 2. The sense amplifier latch SAL and data latches DLA and DLB for holding the sensing result are provided corresponding to each of the sense amplifiers S/A in the sense amplifier circuit 2.

The sense amplifier latch SAL is connected to the sense amplifier circuit 2 by the transfer bus BUS. The data latches DLA and DLB are configured capable of holding certain data. Data can be sent and received between the sense amplifier latch circuit 3 and the data latch circuit 4, via a local transfer bus LBUS. The sense amplifier latch SAL functions to hold data detected by the sense amplifier circuit 2 and to perform a logical operation with data held by the data latches DLA and DLB and perform control for transferring data with a plurality of the data latches DLA and DLB.

[Data Storage State]

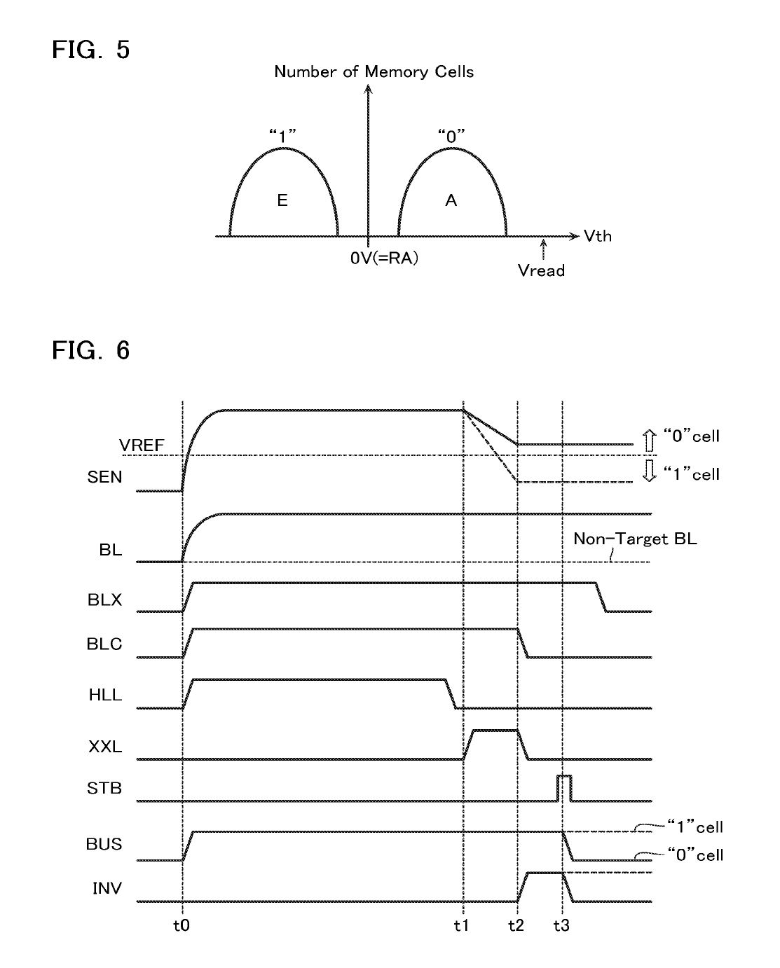

Next, a data storage state of the NAND type flash memory in the present embodiment is described with reference to FIG. 5.

In the present embodiment, the memory cell MC of the NAND type flash memory stores binary data. In this case, threshold voltage distributions corresponding to the data are as in FIG. 5. In the memory cell MC, threshold voltage distributions of E level and A level are set sequentially from a low voltage side. Moreover, data “l” and “0” are allocated to these threshold voltage distributions. Note that E level is a negative threshold voltage distribution obtained by a batch block erase.

In addition, during the read operation of data, a voltage applied to a selected word line WL is set to a read voltage RA which is a voltage between each of the threshold voltage distributions, corresponding to the threshold voltage distribution of the selected memory cell MC. The voltage RA is a voltage roughly intermediate between an upper limit of the threshold voltage distribution E and a lower limit of the threshold voltage distribution A. In the read operation of the NAND type flash memory, an unselected word line WL in the memory cell array 1 is supplied with a read pass voltage Vread at which the unselected memory cell MC is conductive irrespective of data. During the read operation of binary data, read of data is realized by detecting whether a current flows in the NAND string NU at time of read voltage RA or not.

[Read Operation]

Next, the read operation employing the sense amplifier circuit 2 is described with reference to FIGS. 3 and 4. The read operation first charges the node SEN, and discharges a charge of the node SEN by a cell current flowing in the NAND string NU connected to the bit line BL. A discharge amount of the node SEN after a certain fixed time changes according to the cell current. Due to the change, it is distinguished whether the cell is in an erase state (“1” cell) or a write state (“0” cell) (refer to FIG. 3).

Data of the memory cell MC in the NAND string NU connected to the bit line BL is read by the sense amplifier S/A provided one to each of the bit lines BL. A read result of the memory cells MC provided to each of the bit lines BL is held temporarily in the sense amplifier latch SAL, then transferred to the data latch DL. Then, when a data out is performed, data held in the data latch DL is serially outputted sequentially from a specified column address (refer to FIG. 4).

Next, detailed operation of the sense amplifier S/A in the read operation is described with reference to FIG. 6. FIG. 6 is a timing chart of the read operation showing behavior of each of nodes in the sense amplifier S/A.

As shown in FIG. 6, first, at time t0, the signal BLX, the signal HLL, and the signal BLC are set to an “H” state, thereby causing each of transistors T2, T3, and T1 to be in an on state. At that time, setting data of the sense amplifier latch SAL to “1” (=“H”) in advance results in the signal INV which is the inverted signal of data of the sense amplifier latch SAL attaining an “L” state, whereby the node SEN and the bit line BL are charged. Simultaneously during charging, data of the latch is transferred to the transfer bus BUS, whereby the transfer bus BUS is charged to an “H” state.

Note that the bit line BL which is a non-target of the read operation is not charged. Selection, operation, and so on, of the bit line BL which is a non-target of the read operation is mentioned in detail later.

When, at time t1, after the bit line BL has been charged, the signal HLL and the signal XXL are changed causing the transistor T3 to be set to an off state and the transistor T4 to be set to an on state, charging of the node SEN stops. Then, the charge charged to the node SEN begins to discharge due to the cell current of the NAND string NU linked to the bit line BL.

At that time, when the selected memory cell is in an erase state (“1” cell), the discharge amount of the node SEN becomes large due to the large cell current. On the other hand, when the cell is in a write state (“0” cell), the cell current is small, hence the discharge amount of the node SEN is small.

After a certain discharge time, at time t2, the signal XXL is changed, whereby the transistor T4 is set to an off state and discharge of the node SEN is stopped. At that time, an on/off state of the transistor T5 changes according to a potential of the node SEN after discharge. If the potential of the node SEN is greater than or equal to a voltage VREF, then the transistor T5 attains an on state, and if less than the voltage VREF, then the transistor T5 attains an off state.

When the memory cell MC is in a write state (“0” cell), the transistor T5 attains an on state. In the case of this state, at time t3, when the signal STB once rises causing the transistor T6 to attain an on state, the transfer bus BUS is discharged. At this time, inverted data of the transfer bus BUS is transferred to the sense amplifier latch SAL. In other words, the sense amplifier latch SAL attains an “H” state and the signal INV attains an “L” state.

In contrast, when the memory cell MC is in an erase state (“1” cell), the discharge amount of the node SEN becomes large, whereby the transistor T5 attains an off state. In the case of this state, at time t3, even if the signal STB rises causing the transistor T6 to attain an on state, the transfer bus BUS keeps an “H” state without being discharged. Inverted data of this transfer bus BUS is transferred to the sense amplifier latch SAL, whereby the sense amplifier latch SAL attains an “L” state and the signal INV attains an “H” state.

In this manner, the read operation is performed and an inverted signal of read data of each of the sense amplifier latches SAL is transferred to the data latch circuit 4. Since a proportion that this time for charging of the bit line BL (from time t0 to t1) occupies in one time of the read operation is approximately 70 percent of the operation as a whole, then it becomes necessary to reduce charging time of the bit line BL when speeding up the read operation.

[Target of Read Operation]

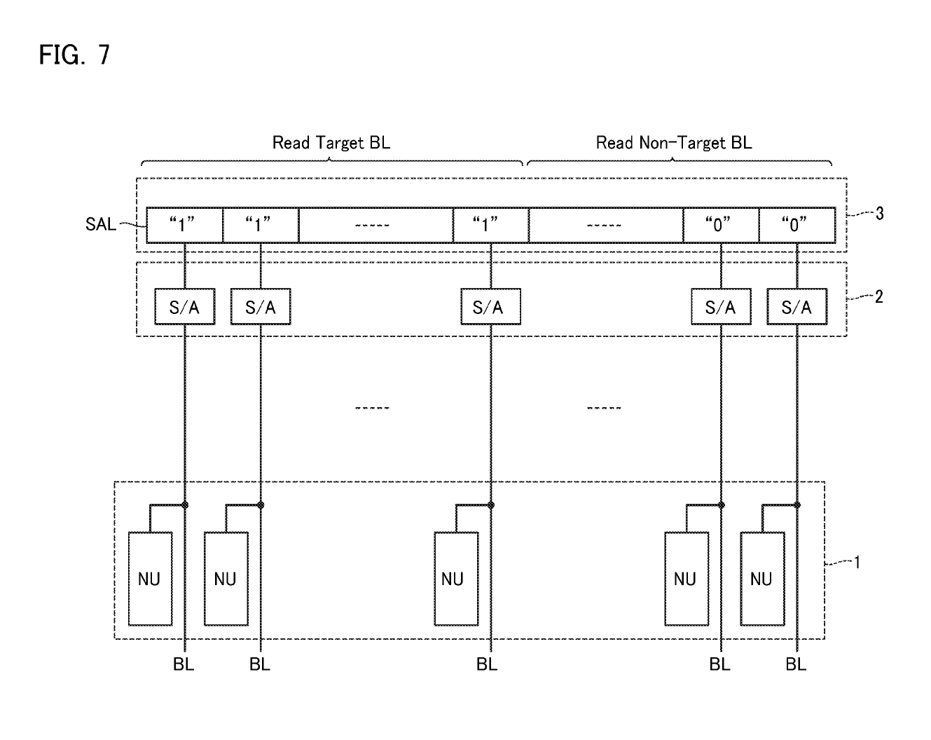

In contrast, the present embodiment does not perform the read operation targeting all of the bit lines BL in the memory cell array 1, but performs the read operation only on a bare minimum of the bit lines BL. Data able to be handled by the host device 5 during operation control is sometimes smaller (for example, 4 KB) than data read from all of the bit lines BL in the memory cell array 1 (for example, 16 KB). In that case, if the read operation is executed targeting all of the bit lines BL in the memory cell array 1, then there is a chance that current consumption for charging of the bit lines BL increases. Therefore, in the present embodiment, the bit lines BL are divided into bit lines BL which are a target of the operation and bit lines BL which are a non-target of the operation, and the bit lines BL that have been made a non-target of the operation are not executed with the charging operation. The number of bit lines BL selected as a target of the operation may correspond to a data unit able to be handled by the host device 5. Moreover, the number of bit lines BL selected as a target of the operation may also differ from the data unit able to be handled by the host device 5. This is described below with reference to FIG. 7. FIG. 7 is a block diagram showing the memory cell array 1 and its peripheral circuits.

FIG. 7 shows the bit lines BL which are to be a target of the read operation and the bit lines which are a non-target of the read operation. In the present embodiment, the read operation is performed not targeting the NAND strings NU connected to all of the bit lines BL in the memory cell array 1, but targeting the NAND strings NU connected to a lesser number than that of the bit lines BL. As shown in FIG. 7, in the present embodiment, half of the bit lines BL included in the memory cell array 1 are chosen as a target of the read operation. Moreover, the bit lines BL which are a target of the read operation are chosen to be disposed on one side of the memory cell array 1. The bit lines BL that are a target of the read operation can be selected in this way because usually, a unit of data handled by the host device 5 during the read operation is smaller than data read from all of the NAND strings NU in the memory cell array 1.

Control of the operation in the cases of selecting a bit line BL to be a target or a non-target of the read operation in this way is described below.

As shown in FIG. 7, only data of the sense amplifier latch SAL linked to a read target bit lines BL is set to “1” (=“H”). In contrast, data of the sense amplifier latch SAL linked to a read non-target bit lines BL is set to “0” (=“L”). As a result, a state of the signal INV (inverted data of data in the sense amplifier latch SAL) at a start time of the read operation is controlled by read target/non-target.

At a charging start time (time t0) of the bit line BL in the read operation shown in FIG. 6, the read target bit line BL has the signal INV attaining an “L” state, whereby the bit line BL is charged. In contrast, the read non-target bit line BL has the signal INV attaining an “H” state at the charging start time (time t0) of the bit line BL, whereby the bit line BL is not charged.

In this way, the semiconductor memory device of the present embodiment is configured to execute the read operation on selected memory cells MC connected to those of the plurality of bit lines BL that are to be a target of the read operation, and not to execute the charging operation on those of the bit lines BL that are not to be a target of the read operation.

[Advantages]

In the semiconductor memory device of the present embodiment, a current detecting type sense amplifier S/A is employed in the read operation. In this current detecting type sense amplifier S/A, the read operation is performed in a state where the bit line BL connected to the selected memory cell MC is charged and the read current is being passed through the bit line BL. Therefore, there is a risk that current consumption during the read operation increases.

Moreover, in a conventional semiconductor memory device, in the case of data being read from the memory cell array 1, one page's worth of data was read from all of the NAND cell units NU in one block BLK. In this case, when executing the read operation in the memory cell array 1, in order to read one page of data, all of the bit lines BL need to be charged, whereby current consumption required in charging of the bit lines BL increases. There is a risk that if it is attempted to suppress a consumed amount of current to a constant amount during this charging of the bit lines BL, then time of the charging lengthens. Furthermore, there was also a risk that if the data unit able to be handled by the host device 5 was smaller than one page's worth of data, unnecessary time would be taken in processing of the read data.

To counter this, as shown in FIG. 7, the semiconductor memory device of the present embodiment executes the read operation targeting a portion of the NAND strings NU in the memory cell array 1. If the data unit able to be handled by the host device 5 is half of one page of data, then selecting half of the bit lines BL in the memory cell array 1 as a target of the operation makes it possible to perform the write operation in a manner where only the data unit able to be handled by the host device 5 is read. Moreover, performing control so as to not perform the charging operation in the bit lines BL that are a non-target of the read operation makes it possible to reduce the number of bit lines BL through which the read current is continued to be passed, whereby current consumption can be greatly reduced.

In addition, when a current value employed in the read operation of the semiconductor memory device is a certain value, then a portion of current of the bit lines BL that are a non-target of the read operation can be employed in the charging operation of the bit lines BL which are a target of the read operation.

In the semiconductor memory device of the present embodiment, a charging level and a charge current amount of the bit lines BL is controlled by the control voltage BLC applied to the gate of the transistor T1 in the sense amplifier S/A shown in FIG. 3. Temporarily raising the control voltage BLC of the transistor T1 during charging of the read target bit line BL enables current flowing in the bit line to be increased. As a result, it is possible to speed up charging of the bit line BL. As mentioned above, speeding up the charging time that occupies the greater part of the read operation time allows speeding up of the read operation to be realized. Note that returning the control voltage BLC of the transistor T1 to a certain level after a certain time from the start of charging enables the charging level of the bit line BL to be maintained.

The semiconductor memory device can be configured such that these controls of the operation can be made effective by commands issued by the host device 5.

### Second Embodiment

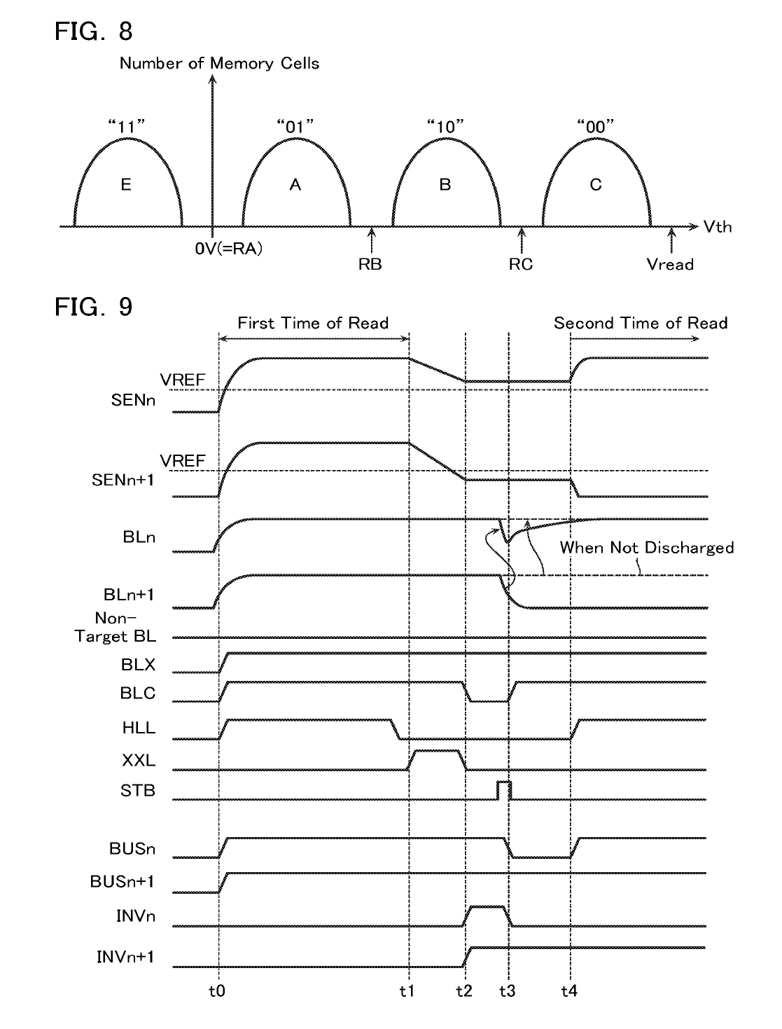

Next, a second embodiment of the present invention is described with reference to FIGS. 8 and 9. An overall configuration of a semiconductor memory device in the second embodiment is similar to that in the first embodiment, hence a detailed description of the overall configuration is omitted. In addition, places having a configuration similar to in the first embodiment are assigned with symbols identical to those assigned in the first embodiment, and a duplicated description of such places is omitted. The above first embodiment was described as a read operation in an example where the memory cell MC holds binary data. In contrast, the present embodiment differs from the first embodiment in that the memory cell MC holds four-level data.

[Data Storage State]

Next, a data storage state of a NAND type flash memory in the present embodiment is described with reference to FIG. 8.

In the present embodiment, the memory cell MC of the NAND type flash memory stores four-level data. In this case, threshold voltage distributions corresponding to the data are as in FIG. 8. In the memory cell MC, threshold voltage distributions of E level, A level, B level, and C level are set sequentially from a low voltage side. Moreover, data “11”, “01”, “10”, and “00” are respectively allocated to these threshold voltage distributions.

In addition, during the read operation of data, a voltage applied to a selected word line WL is set to read voltages RA, RB, and RC which are voltages between each of the threshold voltage distributions, corresponding to the threshold voltage distributions of the selected memory cell MC. The voltage RA is a voltage roughly intermediate between an upper limit of the threshold voltage distribution E and a lower limit of the threshold voltage distribution A, and is the lowest voltage of the voltages RA, RB, and RC. The voltage RB is larger than the voltage RA, and is a voltage roughly intermediate between an upper limit of the threshold voltage distribution A and a lower limit of the threshold voltage distribution B. The voltage RC is larger than the voltage RB, and is a voltage roughly intermediate between an upper limit of the threshold voltage distribution B and a lower limit of the threshold voltage distribution C. During a read operation of four-level data, an operation for reading lower page data is performed by applying the voltage RB to a selected word line WL, and then an operation for reading upper page data is performed by applying the voltages RA and RC to the selected word line WL. Performing a calculation on results of these operations enables data of the memory cell MC to be read.

[Read Operation]

Next, detailed operation of the sense amplifier S/A in the read operation is described with reference to FIG. 9. FIG. 9 is a timing chart of the read operation showing behavior of each of the nodes in the sense amplifier S/A. FIG. 9 illustrates an example where read of the memory cells MC connected to selected bit lines BLn and BLn+1 is performed. Moreover, FIG. 9 shows the node SEN, the signal INV, and the transfer bus BUS corresponding to the selected bit lines BLn and BLn+1 by, respectively, nodes SENn and SENn+1, signals INVn and INVn+1, and transfer buses BUSn and BUSn+1.

The read operation shown in FIG. 8 is an upper page read operation and performs two times of the read operation, consecutively. In the first time of the read operation, the selected word line WL is applied with the voltage RA to determine whether the selected memory cell MC is conductive or not. Moreover, in the second time of the read operation, the selected word line WL is applied with the voltage RC to determine whether the selected memory cell MC is conductive or not.

The charging operation of the bit line BL from time t0 to time t1 is a similar operation to the operation described in the first embodiment. This charging operation of the bit line BL causes the node SEN and the bit line BL to be charged. Simultaneously during charging, data of the latch is transferred to the transfer buses BUSn and BUSn+1, whereby the transfer buses BUSn and BUSn+1 are charged to an “H” state. Note that the bit line BL which is a non-target of the read operation is not charged. Selection, operation, and so on, of the bit line BL which is a non-target of the read operation is mentioned in detail later.

When, at time t1, after the bit line BL has been charged, the signal HLL and the signal XXL are changed causing the transistor T3 to be set to an off state and the transistor T4 to be set to an on state, charging of the node SEN stops. Then, the charge charged to the node SEN begins to discharge due to the cell current of the NAND string NU linked to the bit line BL.

In the case where the voltage RA is being applied to the selected word line WL, when the selected memory cell is in an erase state (“11” cell), the discharge amount of the node SEN becomes large due to the large cell current. On the other hand, when the cell is in a write state (“01”, “10”, and “00” cell), the cell current is small, hence the discharge amount of the node SEN is small.

After a certain discharge time, at time t2, the signal XXL is changed, whereby the transistor T4 is set to an off state and discharge of the node SEN is stopped. At that time, an on/off state of the transistor T5 changes according to a potential of the node SEN after discharge. If the potential of the node SEN is greater than or equal to a voltage VREF, then the transistor T5 attains an on state, and if less than the voltage VREF, then the transistor T5 attains an off state.

In the example shown in FIG. 9, the memory cell MC connected to the bit line BLn is in a write state, whereby the transistor T5 attains an on state. In the case of this state, at time t3, when the signal STB once rises causing the transistor T6 to attain an on state, the transfer bus BUSn is discharged. At this time, inverted data of the transfer bus BUSn is transferred to the sense amplifier latch SAL. In other words, the sense amplifier latch SAL attains an “H” state and the signal INVn attains an “L” state.

In contrast, the memory cell MC connected to the bit line BLn+1 is in an erase state and the discharge amount of the node SEN becomes large, whereby the transistor T5 attains an off state. In the case of this state, at time t3, even if the signal STB rises causing the transistor T6 to attain an on state, the transfer bus BUSn+1 keeps an “H” state without being discharged. Inverted data of this transfer bus BUSn+1 is transferred to the sense amplifier latch SAL, whereby the sense amplifier latch SAL attains an “L” state and the signal INVn+1 attains an “H” state.

In this manner, the read operation is performed and an inverted signal of read data of each of the sense amplifier latches SAL is transferred to the data latch circuit 4.

The memory cell MC connected to the bit line BLn has a threshold voltage state higher than the voltage RA. As a result, in the second time of the read operation, there is a need for an operation to confirm whether the memory cell MC connected to the bit line BLn has a threshold voltage state higher than the voltage RC or not. Therefore, even at time t3 and after, the bit line BLn continues to be kept charged without being discharged. In contrast, the memory cell MC connected to the bit line BLn+1 has a threshold voltage state lower than the voltage RA. Hence, in the second time of the read operation, there is no need to confirm whether the memory cell MC connected to the bit line BLn+1 has a threshold voltage state higher than the voltage RC or not. Therefore, at time t3, the bit line BLn+1 is discharged.

From time t4, the selected word line WL is applied with the voltage RC, whereby the second time of the read operation is executed. Control of the second time of the read operation is similar to that of the first time of the read operation, hence a description of that control is omitted.

This read operation lets it be read whether the memory cell MC connected to the selected bit line BL is caused to be conductive by the voltages RA and RC or not. Performing a calculation on results of this read operation and results of a lower page data read operation enables data of the memory cell MC to be read.

As shown in FIG. 9, in the case where, after the first time of the read operation, an undischarged bit line BLn and a discharged bit line BLn+1 are adjacent to each other, the undischarged bit line BLn is affected by capacitive coupling from the discharged bit line BLn+1. As a result, a potential of the undischarged bit line BLn falls temporarily. In that case, it is required to wait until the potential of the bit line BLn recovers sufficiently to a specified value, and this waiting time also occupies a large proportion of the read operation. In other words, when speeding up the read operation, it becomes necessary to reduce time for recharging of the bit line BLn (from time t3 to time t4) in the second time of the read operation in the read operation.

[Target of Read Operation]

In contrast, the present embodiment too does not perform the read operation targeting all of the bit lines BL in the memory cell array 1, but performs the read operation only on a bare minimum of the bit lines BL. This is an operation similar to that of the first embodiment described with reference to FIG. 7.

In the present embodiment too, similarly to in the first embodiment, the read operation can be performed not targeting the NAND strings NU connected to all of the bit lines BL in the memory cell array 1, but targeting the NAND strings NU connected to a lesser number than that of the bit lines BL (refer to FIG. 7). The semiconductor memory device of the present embodiment too is configured to execute the read operation on selected memory cells MC connected to those of the plurality of bit lines BL that are to be a read target, and not to execute the charging operation on those of the bit lines BL that are not to be a read target.

[Advantages]

As shown in FIG. 7, the semiconductor memory device of the present embodiment executes the read operation targeting a portion of the NAND strings NU in the memory cell array 1. Performing control so as to not perform the charging operation in the bit lines BL that are a non-target of the read operation makes it possible to reduce the number of bit lines BL through which the read current is continued to be passed, whereby current consumption can be greatly reduced.

Now, in the case of control to execute the read operations consecutively, a portion of the memory cells MC sometimes no longer require a read operation of a certain number of times or more. If the bit lines BL connected to the memory cells MC for which the read operation has been completed are discharged at this time, adjacent bit lines BL are affected by capacitive coupling from the discharged bit lines BL, causing a voltage of those adjacent bit lines BL to fall temporarily. There is a problem of it being required to wait until that bit line voltage recovers sufficiently to a specified value, whereby the read operation takes time.

However, as shown in FIG. 7, the semiconductor memory device of the present embodiment makes it possible to reduce the number of bit lines BL through which the read current is continued to be passed, whereby current consumption can be greatly reduced. It is therefore possible to perform control to not discharge the bit lines BL connected to the memory cells MC for which the read operation has been completed. This is because the semiconductor memory device of the present embodiment greatly reduces current consumption, hence even if there is current consumption equivalent to the bit lines BL connected to the memory cells MC for which the read operation has been completed being left charged, a failure in operation does not occur.

As shown in FIG. 9, the selected bit line BLn+1 for which read of data required in the first time of the read operation has been completed can also be left charged for the second time of the read operation and after (bit line BLn+1 shown by a broken line). Since there is no discharging of the bit line BLn+1, the bit line BLn is unaffected by capacitive coupling hence the potential of the bit line BLn does not fall. In that case, time for recharging of the bit line BLn (from time t3 to time t4) is no longer required, thereby enabling the read operation to be speeded up.

These controls can be realized using the data latch circuit 4 and the sense amplifier latch circuit 3. For example, information on whether the bit line BL is a read target or non-target is stored in advance in the data latch DLB. Then, after the first time of the read operation, data read into the sense amplifier latch SAL is transferred to and stored in the data latch DLA, and the information on whether the bit line BL is a read target of non-target is transferred from the data latch DLB to the sense amplifier latch SAL. As a result, the bit line BL which is a target of the read operation can always be kept in a charged state, irrespective of whether required data has been read from the bit line BL or not.

Moreover, in the case where there are few harmful effects due to discharging of the bit line BL for which necessary read of data has been completed, it is also possible to perform control discharging the bit line BL connected to the memory cell MC for which the read operation has been completed. In this case, current consumption in the second time of the read operation can be reduced.

In addition, similarly to in the first embodiment, a portion of current of the bit lines BL that are a non-target of the read operation can be employed in the charging operation during the initial read operation of the bit lines BL which are a target of the read operation. In the semiconductor memory device of the present embodiment too, temporarily raising the control voltage BLC of the transistor T1 during charging of the read target bit line BL in the first time of the read operation enables current flowing in the bit line BL to be increased. As a result, it is possible to speed up charging of the bit line BL during the first time of the read operation.

### Third Embodiment

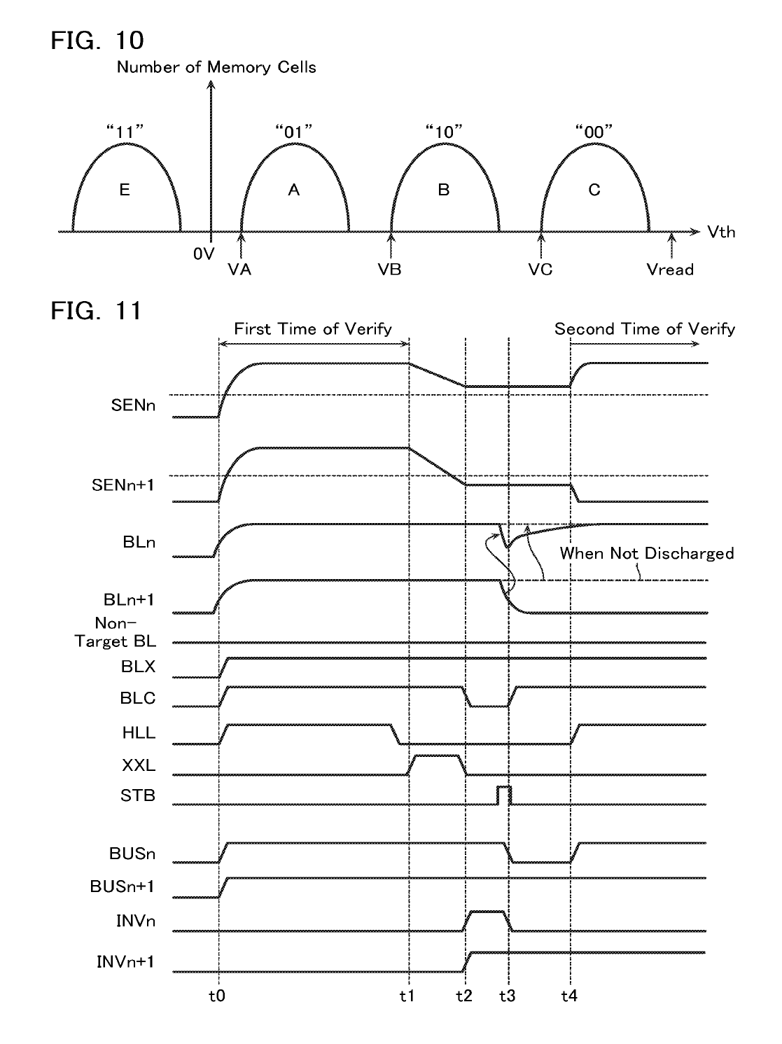

Next, a third embodiment of the present invention is described with reference to FIGS. 10 and 11. An overall configuration of a semiconductor memory device in the third embodiment is similar to that in the first embodiment, hence a detailed description of the overall configuration is omitted. In addition, places having a configuration similar to in the first embodiment are assigned with symbols identical to those assigned in the first embodiment, and a duplicated description of such places is omitted. The above first and second embodiments described a read operation for reading data from a memory cell MC. In contrast, the present embodiment differs from the first and second embodiments in being a write verify operation that, when writing data to a memory cell MC, determines whether desired data has been written to the memory cell MC.

A data storage state of a NAND type flash memory in the present embodiment is described with reference to FIG. 10.

In the present embodiment, the memory cell MC of the NAND type flash memory is assumed to be written with four-level data. In this case, threshold voltage distributions corresponding to data are as shown in FIG. 10. In the memory cell MC, threshold voltage distributions of E level, A level, B level, and C level are set sequentially from a low voltage side. Moreover, data “11”, “01”, “10”, and “00” are respectively allocated to these threshold voltage distributions.

A data write operation in the NAND type flash memory is performed as an operation that applies a write voltage to a selected word line WL to inject electrons from a cell channel into a floating gate electrode by FN tunneling. In this case, a potential of the cell channel is controlled according to write data. As a result, the memory cell MC is set to a certain threshold voltage distribution state.

During this data write, a write verify operation for determining whether a threshold voltage of the memory cell is a certain value or not is executed. Voltages VA, VB, and VC indicate write verify voltages applied for confirming whether write has been completed when performing write to each of the threshold voltage distributions A, B, and C. The voltages VA, VB, and VC are respectively set to lower limit values of the threshold voltage distributions A, B, and C.

During the write verify operation of four-level data, the voltages VA, VB, and VC are applied to the selected word line WL to read whether desired data has been written to the selected memory cell MC or not.

[Write Verify Operation]

Next, detailed operation of the sense amplifier S/A in the write verify operation is described with reference to FIG. 11. FIG. 11 is a timing chart of the write verify operation showing behavior of each of the nodes in the sense amplifier S/A.

In the write verify operation when writing four-level data, three times of the verify operation are performed, consecutively. In the first time of the verify operation, the selected word line WL is applied with the voltage VA to determines whether the selected memory cell MC is conductive or not. Moreover, in the second time and third time of the verify operation, the selected word line WL is applied with the voltages VB and VC, respectively, to determine whether the selected memory cell MC is conductive or not.

The first time of the verify operation from time t0 to time t4 is a similar operation to the first time of the read operation described in the second embodiment, hence a description thereof is omitted. The first time of the verify operation is performed, and an inverted signal of read data in each of the sense amplifier latches SAL is transferred to the data latch circuit 4.

The memory cell MC connected to the bit line BLn has a threshold voltage state higher than the voltage VA. As a result, in the second time of the verify operation, there is a need for an operation to confirm whether the memory cell MC connected to the bit line BLn has a threshold voltage state higher than the voltage VB or not. Therefore, even at time t3 and after, the bit line BLn continues to be kept charged without being discharged. In contrast, the memory cell MC connected to the bit line BLn+1 has a threshold voltage state lower than the voltage VA. Hence, in the second time of the verify operation, there is no need to confirm whether the memory cell MC connected to the bit line BLn+1 has a threshold voltage state higher than the voltage VB or not. Therefore, at time t3, the bit line BLn+1 is discharged.

From time t4, the selected word line WL is applied with the voltage RC, whereby the second time and after of the verify operation is executed. Control of the second time and after of the verify operation is similar to that of the first time of the verify operation, hence a description of that control is omitted. This write verify operation lets it be read whether the memory cell MC connected to the selected bit line BL is caused to be conductive by the voltages VA, VB, and VC or not. As a result, it is determined whether desired data has been written to the memory cell MC or not.

As shown in FIG. 11, in the case where, after the first time of the verify operation, an undischarged bit line BLn and a discharged bit line BLn+1 are adjacent to each other, the undischarged bit line BLn is affected by capacitive coupling from the discharged bit line BLn+1. As a result, a potential of the undischarged bit line BLn falls temporarily. In that case, it is required to wait until the potential of the bit line BLn recovers sufficiently to a specified value, and this waiting time also occupies a large proportion of the verify operation. In other words, when speeding up the verify operation, it becomes necessary to reduce time for recharging of the bit line BLn (from time t3 to time t4) in the second time of the verify operation in the verify operation.

[Target of Write Verify Operation]

In contrast, the present embodiment too does not perform the write verify operation targeting all of the bit lines BL in the memory cell array 1, but performs the write verify operation only on a bare minimum of the bit lines BL. This is an operation similar to that of the first embodiment described with reference to FIG. 7. In the present embodiment, an operation that adopts the read target bit line BL shown in FIG. 7 as a target of the write verify operation is performed.

In the present embodiment too, similarly to in the first embodiment, the write verify operation can be performed not targeting the NAND strings NU connected to all of the bit lines BL in the memory cell array 1, but targeting the NAND strings NU connected to a lesser number than that of the bit lines BL (refer to FIG. 7). The semiconductor memory device of the present embodiment too is configured to execute the write verify operation on selected memory cells MC connected to those of the plurality of bit lines BL that are to be a write verify target, and not to execute the charging operation on those of the bit lines BL that are not to be a write verify target.

[Advantages]

As shown in FIG. 7, the semiconductor memory device of the present embodiment executes the write verify operation targeting a portion of the NAND strings NU in the memory cell array 1. Performing control so as to not perform the charging operation in the bit lines BL that are a non-target of the write verify operation makes it possible to reduce the number of bit lines BL through which the read current is continued to be passed, whereby current consumption can be greatly reduced.

Moreover, in the semiconductor memory device of the present embodiment too, it is possible to perform control to not discharge the bit lines BL connected to the memory cells MC for which the write verify operation has been completed. As shown in FIG. 11, the selected bit line BLn+1 for which read of data required in the first time of the verify operation has been completed can also be left charged for the second time of the verify operation and after (bit line BLn+1 shown by a broken line). Since there is no discharging of the bit line BLn+1, the bit line BLn is unaffected by capacitive coupling hence the potential of the bit line BLn does not fall. In that case, time for recharging of the bit line BLn (from time t3 to time t4) is no longer required, thereby enabling the write verify operation to be speeded up.

In the case where there are few harmful effects due to discharging of the bit line BL for which necessary read of data has been completed, it is also possible to perform control discharging the bit line BL connected to the memory cell MC for which the verify operation has been completed. In this case, current consumption in the second time of the verify operation can be reduced.

In addition, similarly to in the first embodiment, a portion of current of the bit lines BL that are a non-target of the write verify operation can be employed in the charging operation during the initial verify operation of the bit lines BL which are a target of the write verify operation. In the semiconductor memory device of the present embodiment too, temporarily raising the control voltage BLC of the transistor T1 during charging of the verify target bit line BL in the first time of the verify operation enables current flowing in the bit line BL to be increased. As a result, it is possible to speed up charging of the bit line BL during the first time of the verify operation.

### Another Example of Third Embodiment

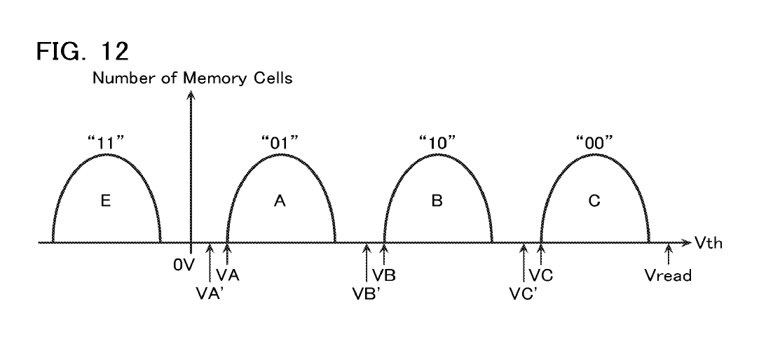

A write verify operation in a NAND type flash memory of the present example is described with reference to FIG. 12.

As mentioned above, the data write operation in the NAND type flash memory is performed as an operation that applies a write voltage to a selected word line WL to inject electrons from a cell channel into a floating gate electrode by FN tunneling. As a result, the memory cell MC is set to a certain threshold voltage distribution state.

At this time, an operation is sometimes performed that controls the write voltage applied to the selected word line WL coarsely until the memory cell MC reaches the certain threshold voltage, and then controls the write voltage finely, thereby improving accuracy and speed of the write operation.

During this data write too, a write verify operation for determining whether a threshold voltage of the memory cell is a certain value or not is executed. Voltages VA, VB, and VC indicate write verify voltages applied for confirming whether write has been completed when performing write to each of the threshold voltage distributions A, B, and C. The voltages VA, VB, and VC are respectively set to lower limit values of the threshold voltage distributions A, B, and C.

In addition, voltages VA′, VB′, and VC′ indicate write verify voltages applied for confirming whether a stage for starting fine control of the write voltage has been reached when performing write to each of the threshold voltage distributions A, B, and C.

During the write verify operation of four-level data, the voltages VA′, VB′, and VC′ are applied to the selected word line WL to determine a state of the selected memory cell MC. Moreover, the voltages VA, VB, and VC are applied to the selected word line WL to read whether desired data has been written to the selected memory cell MC. In this way, multiple times of a write verify operation can be executed on each of a plurality of threshold voltage distributions A, B, and C, while changing a write verify voltage.

Control during the write verify operation in this case is similar to that in the third embodiment shown in FIG. 11. However, as a result of the number of write verify voltages increasing, the verify operation is repeated six times.

In the present example too, the write verify operation is not performed targeting all of the bit lines BL in the memory cell array 1, but is performed only on a bare minimum of the bit lines BL. Similarly to in the third embodiment, the write verify operation is performed not targeting all of the NAND strings NU in the memory cell array 1, but targeting a lesser number than that of the NAND strings NU. As a result, similar advantages to those of the third embodiment can be obtained.

### Fourth Embodiment

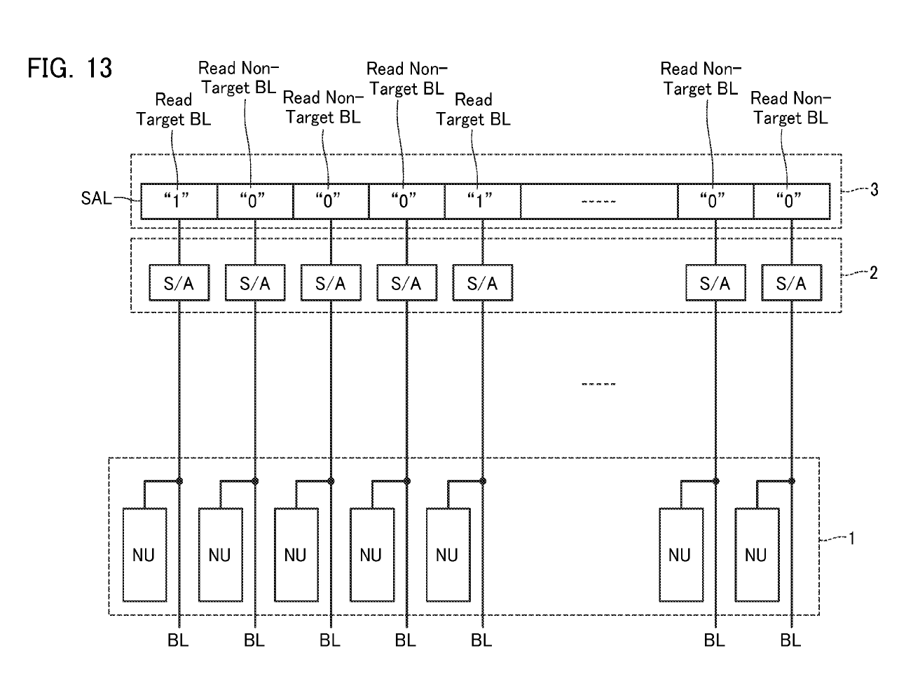

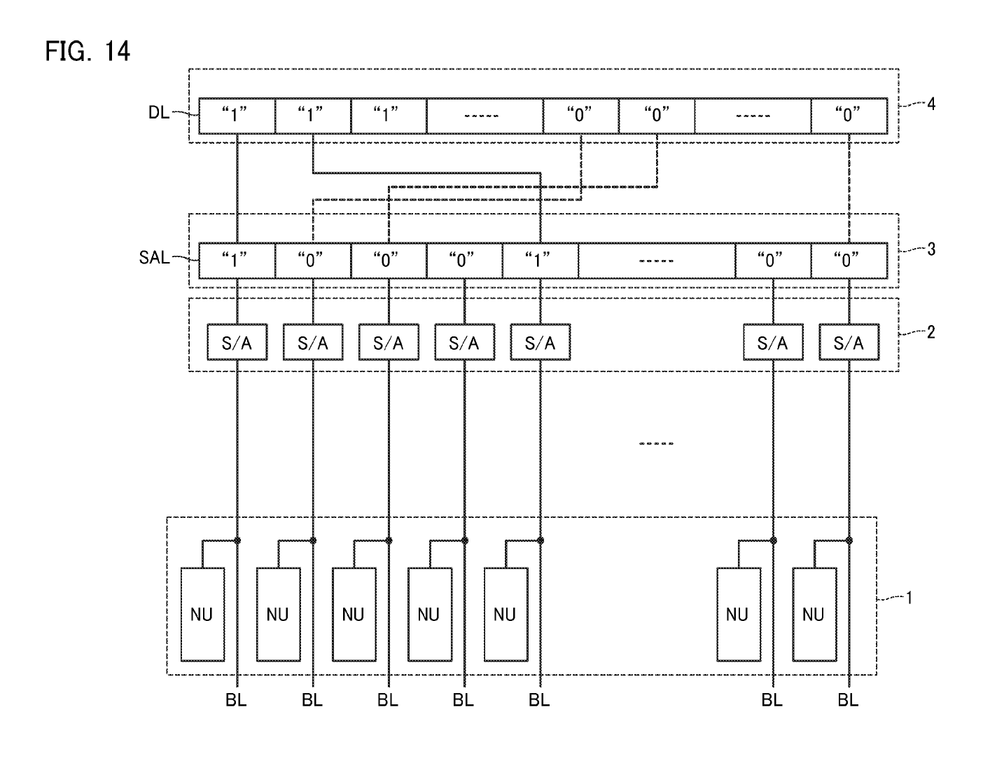

Next, a fourth embodiment of the present invention is described with reference to FIGS. 13 and 14. An overall configuration of a semiconductor memory device in the fourth embodiment is similar to that in the first embodiment, hence a detailed description of the overall configuration is omitted. In addition, places having a configuration similar to in the first embodiment are assigned with symbols identical to those assigned in the first embodiment, and a duplicated description of such places is omitted. In the present embodiment, selection, control of operation, and so on, of the bit line BL which is to be a target of the read operation or write verify operation differ from in the first through third embodiments. In the description below, the read operation is described as an example. However, the configuration of the present embodiment is of course valid also for the write verify operation.

[Target of Read Operation]

In the present embodiment too, the read operation is not performed targeting all of the bit lines BL in the memory cell array 1, but is performed only on a bare minimum of the bit lines BL. This is described below with reference to FIG. 13. FIG. 13 is a block diagram showing the memory cell array 1 and its peripheral circuits.

FIG. 13 shows bit lines BL which are to be a target of the read operation and bit lines BL which are a non-target of the read operation. In the present embodiment, the read operation is performed not targeting the NAND strings NU connected to all of the bit lines BL in the memory cell array 1, but targeting the NAND strings NU connected to a lesser number than that of the bit lines BL. When the data unit able to be handled by the host device 5 is 4 KB and one page of data is 16 KB, the number of bit lines BL to be a read target may be set to a quarter (¼) of the entirety. If the number of bit lines BL to be a read target is set to a quarter (¼) of the entirety, every fourth bit line BL in the memory cell array 1 may be selected to be a read target.

As shown in FIG. 13, only data of the sense amplifier latch SAL linked to a read target bit line BL is set to “1” (=“H”). In contrast, data of the sense amplifier latch SAL linked to a read non-target bit line BL is set to “0” (=“L”). As a result, a state of the signal INV (inverted data of data in the sense amplifier latch SAL) at a start time of the read operation is controlled by read target/non-target. As a result, at a time of starting charging of the bit line BL in the read operation, the read target bit line BL is charged. In contrast, the read non-target bit line BL is not charged at a time of starting charging of the bit line BL.

In this way, the semiconductor memory device of the present embodiment is configured to execute the read operation on selected memory cells MC connected to those of the plurality of bit lines BL that are to be a target of the read operation, and not to execute the charging operation on those of the bit lines BL that are not to be a target of the read operation.

The present embodiment too allows advantages similar to those of the above-described embodiments to be obtained. Moreover, because the read target bit lines BL are selected to be non-adjacent to each other, whichever the read target bit line BL, its adjacent bit line BL is always a non-target of the read operation and does not undergo the bit line BL charging operation. As a result, when performing read operations consecutively, a bit line BL discharged after the first time of the read operation never exerts an effect on another bit line BL. Time for recharging of the bit line BL in the second time and after of the read operation can be reduced, thereby making it possible to speed up the read operation.

In addition, as shown in FIG. 14, connection of the data latch circuit 4 and the sense amplifier latch circuit 3 can be changed. As a result, data inputted to the data latch circuit 4 and output data after read can be inputted/outputted with a read target portion collected, hence removing the need for a host side to control a sequence of data.

### Another Example of Fourth Embodiment

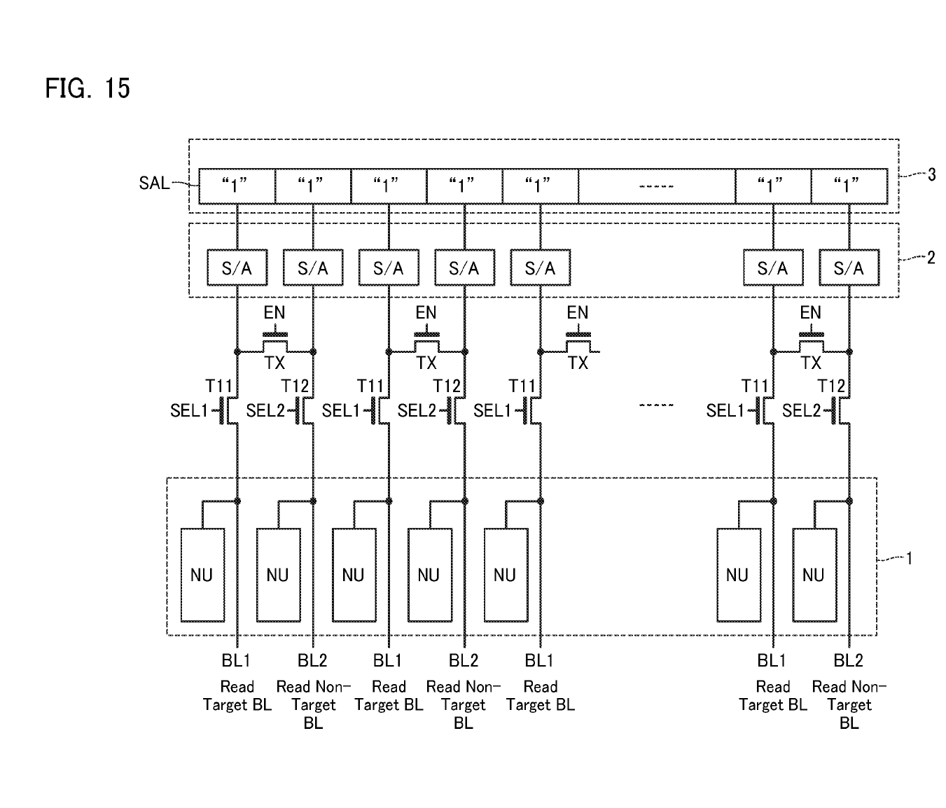

In the present example too, the read operation is not performed targeting all of the bit lines BL in the memory cell array 1, but is performed only on a bare minimum of the bit lines BL. This is described below with reference to FIG. 15. FIG. 15 is a block diagram showing the memory cell array 1 and its peripheral circuits.

FIG. 15 indicates a bit line BL which is to be a target of the read operation by bit line BL1 and indicates a bit line BL which is a non-target of the read operation by bit line BL2. In the present example too, the read operation is performed not targeting the NAND strings NU connected to all of the bit lines BL in the memory cell array 1, but targeting the NAND strings NU connected to a lesser number than that of the bit lines BL. As shown in FIG. 15, in the present example, half of the bit lines BL included in the memory cell array 1 are chosen as a target of the read operation. Moreover, the bit lines BL1 that are a target of the read operation and the bit lines BL2 that are a non-target of the read operation are provided alternately in the memory cell array 1. The bit lines BL that are a target of the read operation can be selected in this way.

In the present example, two adjacent bit lines BL configure a one pair combination. Provided between the two bit lines BL of the one pair is an NMOS transistor TX that has its gate inputted with a signal EN. In addition, connected to the bit line BL1 is an NMOS transistor T11 that has its gate inputted with a signal SEL1, and connected to the bit line BL2 is an NMOS transistor T12 that has its gate inputted with a signal SEL2. Switching the signals SEL1 and SEL2 allows behavior of the bit lines BL1 and BL2 to be controlled. Configuring in such a manner makes it possible that, during an operation on a certain bit line BL, the sense amplifier S/A connected to the bit line BL adjacent to the certain bit line BL is also employed in support of the operation.

As shown in FIG. 15, during the charging operation of the bit line BL, data of the sense amplifier latches SAL linked to all of the bit lines BL is set to “1” (=“H”). At this time, a setting of signal SEL1=“H” and signal SEL2=“L” is made, whereby the bit line BL1 and the sense amplifier circuit 2 are connected and the bit line BL2 and the sense amplifier circuit 2 are disconnected. Simultaneously, by setting the signal EN to “H”, the bit line BL1 is connected also with the sense amplifier circuit on a bit line BL2 side. Inputting all of the sense amplifier latches SAL with data “1” in advance enables charging of the bit line BL1 to be performed from two of the sense amplifiers S/A, whereby a charging speed of the bit line BL can be speeded up. After completion of charging of the bit line BL1, the signal EN is set to “L”, and the read operation executed in a state where the sense amplifier on the bit line BL2 side is disconnected from the bit line BL1.

In this way, the semiconductor memory device of the present embodiment is configured such that a power supply terminal VDD of the sense amplifier S/A corresponding to all of the bit lines BL is employed in the charging operation of the bit lines BL connected to the memory cells MC targeted by the read operation.

In the present embodiment too, because the read target bit lines BL are selected to be non-adjacent to each other, whichever the read target bit line BL, its adjacent bit line BL is always a non-target of the read operation and does not undergo the bit line BL charging operation. As a result, when performing read operations consecutively, a bit line BL discharged after the first time of the read operation never exerts an effect on another bit line BL. Time for recharging of the bit line BL in the second time and after of the read operation can be reduced, thereby making it possible to speed up the read operation. Moreover, connecting the sense amplifier S/A connected to the read non-target bit line BL2 to the read target bit line BL1 enables charging from two sense amplifiers during charging of the bit line BL1, whereby the charging time of the bit line BL can be reduced.

[Other]

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, the above embodiments described an example where the number of bit lines BL to be a read target is set to a quarter (¼) of all the bit lines BL, but the present invention is not limited to this configuration. For example, half of the bit lines BL included in the memory cell array 1 may be selected as a target of the read operation. Bit lines BL that are a target of the read operation and bit lines BL that are a non-target of the read operation may be provided alternately in the memory cell array 1. Moreover, data stored in the memory cell is not limited to binary data or four-level data, and may also be eight-level data, and so on.

What is claimed is:

1. (canceled)

2. A memory device, comprising:
a memory cell array including a plurality of memory cells;
a plurality of sense amplifiers connected to the memory cells; and
a control circuit configured to execute a first read operation when the memory device receives a first read command,
wherein the memory device is configured to output first data by executing the first read operation, and a number of bits of the first data is different from a number of bits of the sense amplifiers.

3. The nonvolatile semiconductor memory device according to claim 2, wherein the memory cell is a memory cell configured to store multi-value information allocated to a plurality of threshold voltage distributions.

4. The nonvolatile semiconductor memory device according to claim 3, wherein the control circuit is configured to execute the read operation a plurality of times corresponding to the plurality of threshold voltage distributions.

5. The nonvolatile semiconductor memory device according to claim 4, wherein the control circuit is configured to discharge a bit line corresponding to those of the memory cells from which certain data has been read in a certain time of a read operation.

6. The nonvolatile semiconductor memory device according to claim 4, wherein the control circuit is configured to not discharge a bit line corresponding to those of the memory cells from which certain data has been read in a certain time of a read operation.

7. The nonvolatile semiconductor memory device according to claim 2, wherein the control circuit comprises a clamp transistor provided between a power supply terminal and a bit line, and the clamp transistor is configured capable of changing a charging speed of the bit line by a gate voltage of the clamp transistor being controlled.

8. The nonvolatile semiconductor memory device according to claim 2, wherein the control circuit is configured to, in a read operation, be capable of executing the read operation targeting the memory cell transistors connected to half of the plurality of bit lines.

9. The nonvolatile semiconductor memory device according to claim 2, wherein the control circuit is configured to, in a read operation, be capable of executing the read operation targeting the memory cell transistors connected to a quarter (¼) of the plurality of bit lines.

10. The nonvolatile semiconductor memory device according to claim 2, wherein the control circuit comprises, for each of the bit lines, a clamp transistor provided between a power supply terminal and the bit line, and the control circuit, in the charging operation of the bit lines connected to the memory cell transistors being targeted by the read operation, employs the power supply terminal corresponding to all of the bit lines.

11. The nonvolatile semiconductor memory device according to claim 2, wherein the control circuit comprises a plurality of latch circuits configured to control whether the memory cell transistor connected to the bit line is targeted by the read operation or not based on data set in the latch circuits, each of the latch circuits being connected to a corresponding one of the plurality of sense amplifiers.

12. The memory device according to claim 2, wherein the control circuit is configured to input a predetermined data to a part of the sense amplifiers during the first read operation.

13. The memory device according to claim 12, wherein the control circuit is configured to, in the first read operation, charge a voltage to only selected bit lines, the selected bit lines being electrically connected to the part of the sense amplifiers.
